(19) United States
(12) Patent Application Publication
(10) Pub. No.: US 2005/0178948 A1
(43) Pub. Date: Aug. 18, 2005

(54) Projection method of display device

(75) Inventors: Yuan-Yu Lee, Hsinchu (TW); Chu-Ming Cheng, Hsinchu (TW)

Correspondence Address: Min, Hsieh & Hack, LLP;c/o PortfolioIP, P.O. Box 52050, Minneapolis, MN, 55402, US

(73) Assignee: Young Optics Inc.

(21) Appl. No.: 11/030,138

(22) Filed: Jan. 7, 2005

(30) Foreign Application Priority Data
Feb. 13, 2004 (TW) 093103582

(51) Int. Cl. H01L 27/00

(52) U.S. Cl. 250/208.1

(57) ABSTRACT

A projection method of display device is to divide high-resolution pixels into a plurality of image-forming units with equal pixels in an appropriate arrangement. A light valve has the same resolution as the image-forming unit, and each pixel thereon is a diamond shape. The diamond pixels are close to one another and staggered in alternate rows. By oscillating the projection path of the light valve, the image-forming position of the light vale produces an appropriate shift. The light valve projects different images corresponding to the position of image-forming units and oscillates quickly such that a cheap and low-resolution light valve can be used to project a high-resolution image and smoothes the edges of the image.

### FIELD OF THE INVENTION

The present invention relates to a display device, and more particularly to a projection method of a display device for raising image quality.

### BACKGROUND OF THE INVENTION

Using a light valve of low-resolution pixel to achieve a high-resolution image can raise the yield rate of a display device and lower the cost. As shown in FIG. 1, a conventional display device 10 generates a light beam by a light source 11. The light beam is converged by lens 12 and then projected onto a light valve 13, and is modulated to become an image light beam by the light valve 13, and afterwards passes through a plane mirror 14. The plane mirror 14 oscillates forward and backward by using an oscillation device 15. The path lengths of the light beam are different after refracted by the oscillating plane mirror 14, and therefore the light path 16 moves for a tiny distance to the light path 16′ and oscillates back and forth. Besides, a control device 17 makes the light valve 13 to drive the plane mirror 14 in accordance with the oscillation device 15 for forming an image at the light paths 16 and 16′. Finally, the projection lens 18 projects the image onto the screen 19.

As shown in FIG. 2, the light valve 13 of the conventional display device 10 makes a movement of a pixel distance by oscillating the light path 16 mentioned above, for projecting the pixels 161 and 161′ back and forth in a period when human vision temporarily remains, and forms an image of twice high resolution, and thereby a low-resolution light valve without close pixels can substitute a high-cost, low-yield and high-resolution light valve. However, such method is merely oscillating the original image back and forth to form a continuous image. The image not only has visible low-resolution saw-toothed edges at the front and rear ends in the moving directions, but also has saw-toothed figures and lines owing to low resolution, thus the quality thereof is affected and cannot substitute a real high-resolution image. Meanwhile, a low-resolution light valve without close pixels cannot reduce its size, and it is hard to reduce the whole size of the display device.

### SUMMARY OF THE INVENTION

One object of the present invention is to provide a projection method of a display device, which smoothes the edges of the image by not projecting the pixels at the front and rear end of moving directions of the image-forming unit.

Another object of the present invention is to provide a projection method of a display device, which smoothes the edges of the figures and lines of the images and raises the image resolution by using a low-resolution light valve to project different images of image-forming unit at different oscillating locations.

Still another object of the present invention is to provide a projection method of a display device, which reduces the size of the light valve and lowers the volume of the whole display device by making the pixels of the light valve a diamond shape and making the pixels in the image-forming unit close to one another and arranged compactly.

For attaining the objects mentioned above, the method of the present invention is to divide high-resolution pixels into a plurality of image-forming units with equal pixels in an appropriate arrangement. A light valve has the same resolution as the image-forming unit, and each pixel thereon is a diamond shape. The diamond pixels are close to one another and staggered in alternate rows. By oscillating the projection path of the light valve, the image-forming position of the light vale produces an appropriate shift. The light valve projects different images corresponding to the position of image-forming units and oscillates quickly such that a cheap and low-resolution light valve can be used to project a high-resolution image and smoothes the edges of the image.

### BRIEF DESCRIPTION OF THE DRAWINGS

FIG. 1 is the diagram showing the projection method of a conventional projection display device.

FIG. 2 is the diagram showing the forming and moving of pixels in a convention projection display device.

FIG. 3 is the diagram showing the arrangement of the pixels in an image of a general digital television.

FIG. 4A is the diagram showing the arrangement of the pixels in the static image-forming unit.

FIG. 4B is the diagram showing the arrangement of the pixels in the dynamic image-forming unit.

FIG. 5 is the diagram showing the imaging and oscillating of the pixels on the light valve according to the invention.

FIG. 6 is the flow chart showing the projection method of the display device according to the invention.

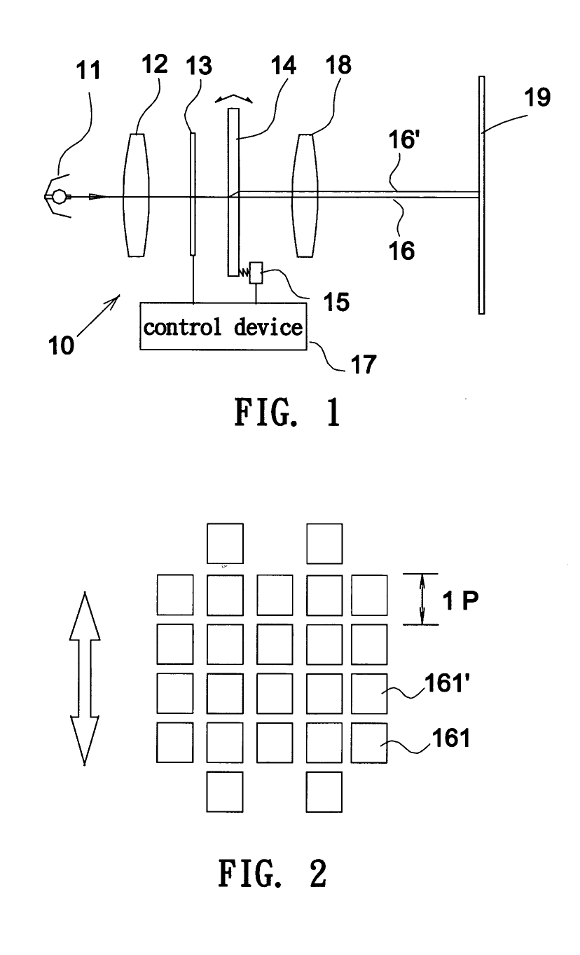

### DETAILED DESCRIPTION OF THE PREFERRED EMBODIMENT

The above and other objects, advantages, and features of the present invention can be understood from the following detailed description of the invention when considered in connection with the accompanying drawing below.

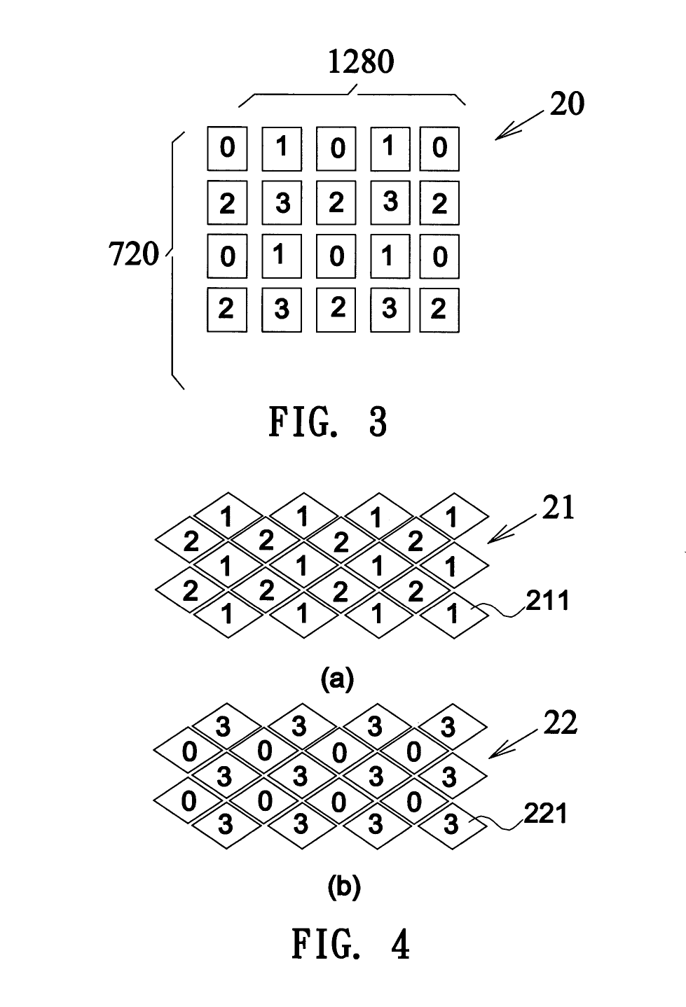

In the present invention a low-resolution light valve achieves a high-resolution image, as shown in FIG. 3, a HDTV picture 20 of resolution 1280×720 is taken for example. First, by being staggered in alternate rows, the pixels on the high-resolution picture 20 are divided into a static image-forming unit 21 (as shown in FIG. 4A) and a dynamic image-forming unit 22 (as shown in FIG. 4B), and the resolution of these two image-forming units is reduced to half of 1280×720, that is, 640×360, and the pixels 211 and 221 are in a diamond shape for each pixel to be close to each other side by side, and are staggered in alternate rows in order to form a pixel array of small area.

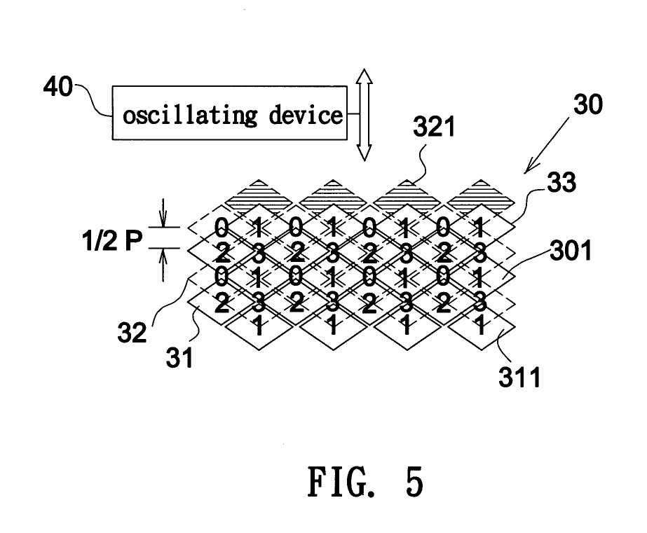

As shown in FIG. 5, there is a low-resolution light valve 30 of resolution 640×360 on the projection display device, and the pixel 301 thereon is in a diamond shape that is the same as pixels 211 and 221 and is close to one another side by side and is staggered in alternate rows for reducing the area of the light valve 30, and then by the quick oscillation of the oscillating device 40, the light path projected by the light valve 30 shifts a distance of a half pixel long, and the moving directions are corresponding to the relative positions of the image-forming units 21 and 22. In this embodiment the directions are vertically up and down for illustration, the light valve 30 projects back and forth on an initial position 31 (as shown in solid lines) and a shifted position 32 (as shown in dotted lines), and is correspond to the frequency of the oscillating device 40. When the light valve 30 projects on the initial position 31, it projects the image of the static image-forming unit 21, and when the light valve 30 projects on the shifted position 32, it projects the image of the dynamic image-forming unit 22.

In addition, the diamond-shaped dynamic image-forming unit 22 and static image-forming unit 21 are staggered in alternate rows, and the oscillating device 40 makes the light valve 30 to shift upward and downward for a distance of a half pixel, thus, the imaging of the dynamic image-forming unit 22 is just between each pixel of the static image-forming unit 21, and forms a arrangement same as the original resolution 1280×720. During the time when human vision temporarily remains (about 0.1 second), the light valve projects back and forth for the images of the dynamic image-forming unit 22 and the static image-forming unit 21 to appear at the same time, forming a high-resolution image.

The close pixels of the dynamic image-forming unit 22 and the static image-forming unit 21 form a high-resolution image, therefore saw-toothed edges of the figures and lines of the images caused by diamond pixels can be more smooth so that human eye cannot be aware of. Besides, when the dynamic image-forming unit 22 forms an image at the shifted position 32, the saw-toothed pixel row 321 at the forefront of the moving direction does not form images in order to be merged into the edge of the pictures and substituted by second high-resolution pixel row 33. The distance between each pixel in the high-resolution pixel row 33 is half of the low-resolution pixel row 321 for smoothing the edges of the picture, for the upper edge of the picture to be seemed less saw-toothed. Similarly, the pixel row 311 at the moving direction from the initial position 31 relative to the shifted position 32 can be not forming images for smoothing the lower saw-toothed edge of picture. The process that the diamond-shaped pixels reduce the area of the light valve and raise the resolution makes the figures and lines of the image smoother.

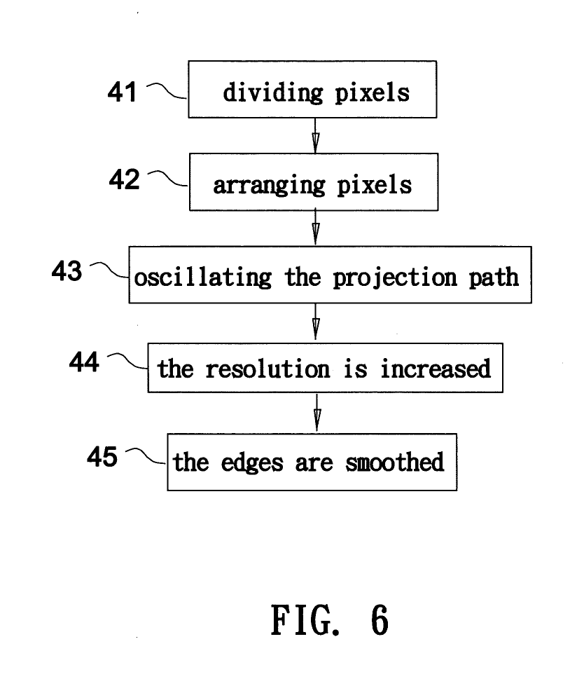

Therefore, as shown in FIG. 6, by the projection method of the invention, the step 41 divides high-resolution pixels into a plurality of image-forming units with equal pixels in an appropriate arrangement. In the step 42 a light valve has the same resolution as the image-forming unit, and each pixel thereon is a diamond shape. The diamond pixels are close to one another and staggered in alternate rows. In the step 43 by oscillating the projection path of the light valve, the image-forming position of the light vale produces an appropriate shift. In the step 44 the light valve projects different images corresponding to the position of image-forming units and oscillates quickly such that a cheap and low-resolution light valve can be used to project a high-resolution image and smoothes the edges of the image.

While a preferred embodiment of the present invention have been described herein for the purpose of illustration, many modifications and changes will become apparent to those skilled in the art. Accordingly, the appended claims are intended to encompass all such modifications and changes as fall within the true spirit and scope of this invention.

1. A projection method of display device, comprising the steps of:
making all pixels on a light valve in the display device to be diamond-shaped;
arranging each of the pixels close to one another;
oscillating a projection path of the light valve for shifting the image-forming positions of each pixel; and
marking the light valve projecting different images at different image-forming positions.

2. The projection method of display device according to claim 1, wherein the diamond-shaped pixels are staggered in alternate rows.

3. The projection method of display device according to claim 1, wherein the projection path of the light valve oscillates back and forth to make a shift.

4. The projection method of display device according to claim 1, wherein the shifting distance of the pixel image-forming position is half a pixel.

5. The projection method of display device according to claim 1, wherein the light valve uses images with multiple resolution of the light valve to be divided into a plurality of image-forming unit in coordination with the arrangement position, for making the resolution of the light valve to be equal to the resolution of the image-forming unit.

6. The projection method of display device according to claim 5, wherein the light valve projects different images of the image-forming unit corresponding to the position of the image-forming unit.

7. The projection method of display device according to claim 6, wherein the image-forming unit does not form images on a pixel row at the forefront row of the moving direction.

8. The projection method of display device according to claim 6, wherein the image-forming unit does not form images on a pixel row at the last row of the moving direction.

9. The projection method of display device according to claim 6, wherein the moving directions are corresponding to relative positions of the image-forming units.
